(19) United States
(12) Patent Application Publication
(10) Pub. No.: US 2025/0056982 A1
(43) Pub. Date: Feb. 13, 2025

(54) DISPLAY DEVICE

(71) Applicant: Samsung Display Co., LTD., Yongin-si (KR)

(72) Inventors: Hyun KIM, Yongin-si (KR); Je Won YOO, Yongin-si (KR); Seung Min LEE, Yongin-si (KR)

(21) Appl. No.: 18/631,237

(22) Filed: Apr. 10, 2024

(30) Foreign Application Priority Data
Aug. 9, 2023 (KR) 10-2023-0104157

(51) Int. Cl. H10K 59/127; H10K 59/12; H10K 71/50; H10K 77/10; H10K 102/00

(52) U.S. Cl. CPC H10K 59/127; H10K 59/1201; H10K 71/50; H10K 77/111; H10K 2102/311

(57) ABSTRACT

A display device includes a display panel, which includes a first area including a display area, a second area spaced apart from the first area in a first direction, and a third area located between the first area and the second area and configured to bend, a first substrate including a rigid material, a second substrate disposed on the first substrate and including a flexible material, a protective layer disposed on the second substrate and overlapping the third area, and an alignment mark disposed on the first substrate, a cutting area that overlaps the third area, wherein a portion of the second substrate and a portion of the protective layer are removed from the cutting area, wherein the first substrate at least partially overlaps the cutting area, and wherein the alignment mark is disposed where the first substrate and the cutting area overlap each other.

This application claims priority to Korean Patent Application No. 10-2023-0104157, filed on Aug. 9, 2023, and all the benefits accruing therefrom under 35 U.S.C. § 119, the content of which in its entirety is herein incorporated by reference.

### BACKGROUND

### 1. Field of the Disclosure

The present disclosure relates to a display device.

### 2. Description of the Related Art

As the information-oriented society evolves, various demands for display devices are ever increasing.

A display device may include a display area where images are displayed, and a non-display area around the display area, for example. Such a non-display area is dead space. The width of the dead space in some display devices is being decreased in order to further immerse viewers in the contents displayed on the display area and to increase the aesthetics of the display devices.

### SUMMARY

Aspects of the present disclosure provide a display device with improved reliability, fabricated by removing un-uniform portions of a protective layer.

Aspects of the present disclosure also provide a display device supportive of improved alignment accuracy of elements when the display device is bent through improved visibility of an alignment mark.

It should be noted that objects of the present disclosure are not limited to the above-mentioned object; and other objects of the present disclosure will be apparent to those skilled in the art from the following descriptions.

According to an aspect of the present disclosure, there is provided a display device including a display panel. The display panel includes a first area including a display area, a second area spaced apart from the first area in a first direction, and a third area located between the first area and the second area and configured to bend, wherein the display panel includes a first substrate including a rigid material, a second substrate disposed on the first substrate and including a flexible material, a protective layer disposed on the second substrate and overlapping the third area, and an alignment mark disposed on the first substrate. The display panel includes a cutting area that overlaps the third area, wherein a portion of the second substrate and a portion of the protective layer are removed from the cutting area, wherein the first substrate at least partially overlaps the cutting area, and wherein the alignment mark is disposed at a location where the first substrate and the cutting area overlap each other.

In an embodiment, the cutting area may be located at one or more ends of the third area in a second direction different from the first direction.

In an embodiment, the first substrate may include an opening overlapping the third area, a first subsidiary substrate disposed closer to the first area than to the opening, and a second subsidiary substrate disposed closer to the second area than to the opening. The first subsidiary substrate may include a first non-overlapping portion and the second subsidiary may include a second non-overlapping portion, and the first non-overlapping portion and the second non-overlapping portion may not overlap the second substrate, The alignment mark may overlap at least one of the first non-overlapping portion and the second non-overlapping portion.

In an embodiment, the alignment mark, the first subsidiary substrate, the second subsidiary substrate, and the second substrate may be arranged in an order of the alignment mark, the first subsidiary substrate, the second subsidiary substrate, and the second substrate along a thickness direction of the first substrate when the second substrate is bent at the third area.

In an embodiment, the second substrate may include a cutting portion located in the cutting area and a non-cutting portion located on one side of the cutting portion, and wherein the alignment mark overlaps the cutting portion.

In an embodiment, the non-cutting portion may include a first non-cutting portion disposed on a first side of the cutting portion in a second direction different from the first direction, a second non-cutting portion disposed on a second side of the cutting portion in the first direction, and a third non-cutting portion disposed on a third side of the cutting portion in the first direction, wherein the third side is opposite the second side in the first direction.

In an embodiment, the alignment mark may overlap the third non-cutting portion of the second substrate when the second substrate is bent at the third area.

In an embodiment, the alignment mark may include one or more sides facing a border of the cutting portion.

In an embodiment, the protective layer may include a removed portion located in the cutting area and a non-removed portion located at one or more sides of the removed portion, and the alignment mark may overlap the removed portion.

In an embodiment, the removed portion may overlap the cutting portion.

In an embodiment, the non-removed portion comprises, a first non-removed portion disposed on a first side of the removed portion in a second direction different from the first direction, a second non-removed portion disposed on a second side of the removed portion in the first direction, and a third non-removed portion disposed on a third side of the removed portion in the first direction, wherein the third side is opposite the second side in the first direction.

In an embodiment, a boundary between the cutting portion and the non-cutting portion may correspond to a boundary between the removed portion and the non-removed portion in a thickness direction of the first substrate.

In an embodiment, an angle formed between a side surface of the second substrate and a surface of the first substrate may range from 45 degrees to 90 degrees at the boundary between the cutting portion and the non-cutting portion.

In an embodiment, the display device may further include a processing mark disposed at the boundary between the cutting portion and the non-cutting portion.

In an embodiment, a length of the processing mark in the first direction may range from 10 μm to 100 μm.

In an embodiment, the cutting area may include a first cutting area located closer to the first area with respect to a center line of the third area, and a second cutting area located closer to the second area with respect to a center line of the third area, wherein a length of the first cutting area in the first direction is may be greater than a length of the second cutting area.

In an embodiment, a transmittance of the first substrate may be higher than a transmittance of the second substrate.

In an embodiment, the first substrate further comprises, a first surface on which the second substrate is disposed, a second surface opposite to the first surface, a first side surface disposed adjacent to the third area and located between the first surface and the second surface, and a first inclined surface disposed between the first surface and the first side surface.

In an embodiment, a length of the cutting area in the first direction is greater than or equal to a length of the protective layer.

In an embodiment, the second substrate may include a cutting portion located in the cutting area, the protective layer may include a removed portion located in the cutting area, the cutting portion and the removed portion may overlap each other, and the length of the cutting portion in the first direction may be greater than or equal to a length of the removed portion in the first direction.

According to an embodiment of the present disclosure, the reliability of a display device can be improved by removing un-uniform portions of a protective layer.

According to an embodiment of the present disclosure, the alignment accuracy of elements when a display device is bent can be improved by way of improving the visibility of an alignment mark.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a display device according to an embodiment of the present disclosure.

FIG. 2 is a plan view showing a display panel and driver ICs according to an embodiment.

FIG. 3 is a cross-sectional view showing an example of the display area of a display device according to an embodiment of the present disclosure.

FIG. 4 is a cross-sectional view taken along line X1-X1′ in FIG. 1.

FIG. 5 is a cross-sectional view showing an example of a display device according to the embodiment of FIG. 4 when the display device is bent.

FIG. 6 is a cross-sectional view showing another example of the display device according to the embodiment of FIG. 4 when the display device is bent.

FIG. 7 is an enlarged view of area A of FIG. 2.

FIG. 8 is a plan view showing a portion of a first substrate according to an embodiment.

FIG. 9 is a plan view showing a portion of a second substrate according to an embodiment.

FIG. 10 is a plan view showing a portion of a protective layer according to an embodiment of the present disclosure.

FIG. 11 is a cross-sectional view showing an example, taken along line X2-X2′ of FIG. 7.

FIG. 12 is a cross-sectional view showing another example, taken along line X2-X2′ of FIG. 7.

FIG. 13 is a plan view showing the display device according to the embodiment of FIG. 7 when the display device is bent.

FIG. 14 is an enlarged view of area B of FIG. 13.

FIG. 15 is a cross-sectional view, taken along line X3-X3′ in FIG. 14.

FIG. 16 is a plan view showing a portion of a display device according to another embodiment of the present disclosure.

FIG. 17 is a plan view showing a portion of a first substrate according to another embodiment.

FIG. 18 is a plan view showing a portion of a second substrate according to another embodiment.

FIG. 19 is a plan view showing a portion of a protective layer according to another embodiment of the present disclosure.

FIG. 20 illustrates an example flowchart of a method in accordance with one or more embodiments of the present disclosure.

### DETAILED DESCRIPTION

Example aspects of the present disclosure will now be described more fully hereinafter with reference to the accompanying drawings, in which example embodiments are shown. Aspects supported by the present disclosure may, however, be embodied in different forms and should not be construed as limited to the embodiments set forth herein. Rather, these embodiments are provided so that this disclosure will be thorough and complete, and will filly convey the scope of example aspects of the invention to those skilled in the art.

It will also be understood that when a layer is referred to as being “on” another layer or substrate, the layer can be directly on the other layer or substrate, or intervening layers may also be present. The same reference numbers indicate the same components throughout the specification.

Terms such as, for example, such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

In order to reduce the width of a non-display area of a device, aspects of the present disclosure may include forming a bending area between a pad area and a display area, and the pad area may be positioned under a display panel when the bending area is bent. To this end, a substrate formed of a flexible material that is bendable may be used. As the size of the substrate increases, a substrate formed of a rigid material may be further included in order to maintain the shape.

When the display device is bent, a main area including a display area and a non-display area and a pad area bent under the main area may be accurately aligned with each other by using an alignment mark. Specifically, for example, the elements located at the upper and lower layers may be accurately aligned with each other when the display device is bent. By doing so, the width of the non-display area can be adjusted.

In some aspects, in order to protect the display device from tension or other external forces applied to the elements in the bending area, a protective layer may be included in the bending area.

Hereinafter, embodiments of the present disclosure will be described in detail with reference to the accompanying drawings.

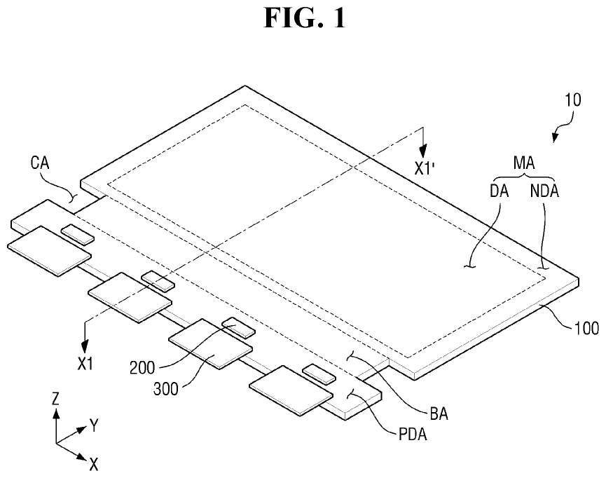

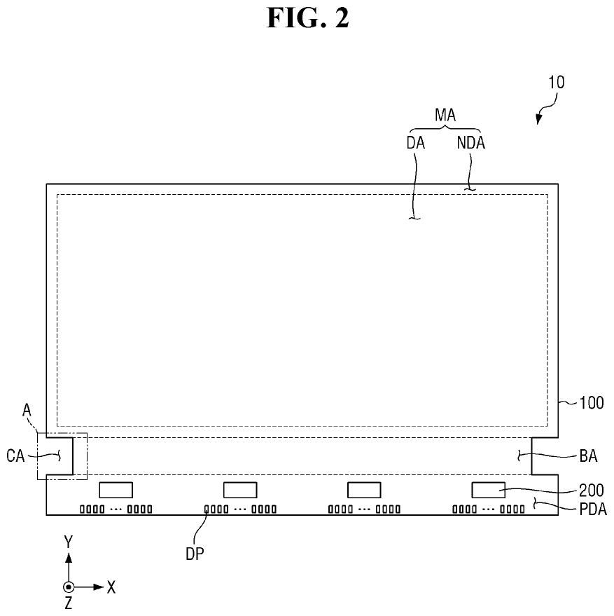

FIG. 1 is a perspective view showing a display device according to an embodiment of the present disclosure. FIG. 2 is a plan view showing a display panel and driver ICs according to an embodiment.

Referring to FIGS. 1 and 2, a display device 10 according to an embodiment of the present disclosure may be capable of displaying moving images or still images. The display device 1 may be used as the display screen of portable electronic devices such as, for example, a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as, for example, a television, a notebook, a monitor, a billboard and the Internet of Things device.

According to an embodiment of the present disclosure, the display device 10 may be a light-emitting display device such as, for example, an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 10. It is, however, to be understood that embodiments supported by the present disclosure are not limited thereto.

The display device 10 according to an embodiment may include a display panel 100, driver integrated circuits (ICs) 200, and circuit boards 300.

The display panel 100 may be formed in a rectangular plane having longer sides in a first direction (x-axis direction) and shorter sides in a second direction (y-axis direction) intersecting the first direction (x-axis direction). Each of the corners where a longer side in the first direction (x-axis direction) meets a shorter side in the second direction (y-axis direction) may be formed at a right angle or may be rounded with a curvature. The shape of the display panel 100 when viewed from the top (e.g., viewed according to a plan view) is not limited to a quadrangular shape, but may be formed as a different polygonal shape, a circular shape, or an elliptical shape.

In the drawings, the first direction (x-axis direction) and the second direction (y-axis direction) intersect each other as respective horizontal and vertical directions. For example, the first direction (x-axis direction) and the second direction (y-axis direction) may be orthogonal to each other. The third direction (z-axis direction) may intersect the first direction (x-axis direction) and the second direction (y-axis direction), and may be, for example, a vertical direction orthogonal to them. Herein, the side indicated by the arrow of each of the first to third directions (x-axis direction, y-axis direction and z-axis direction) may be referred to as a first side, while the opposite side may be referred to as a second side.

The display panel 100 may be formed flat, but embodiments supported by the present disclosure are not limited thereto. For example, the display panel 100 may be formed at left and right ends and may include a curved portion having a constant curvature or a varying curvature. In some aspects, the display panel 100 may be flexible such that the display panel 100 can be curved, bent, folded or rolled.

The display panel 100 may include a main area MA, a bending area BA, and a pad area PDA. The main area MA may include a display area DA where images are displayed, and a non-display area NDA surrounding the display area DA.

In an example, the display area DA may occupy most of the area of the display panel 100. The display area DA may be disposed at the center of display device 100. The display panel 100 may include, disposed in the display area DA, pixels each including a plurality of emission areas and capable of displaying images.

The non-display area NDA may be disposed adjacent to the display area DA. The non-display area NDA may be disposed on the outer side of the display area DA. For example, the non-display area NDA may be disposed outside of the display area DA. The non-display area NDA may surround the display area DA. The non-display area NDA may be defined as the border of the display panel 100.

The bending area BA may be located between the display area DA and the pad area PDA in the second direction (y-axis direction). The bending area BA may extend in the first direction (x-axis direction). The bending area BA may be bent such that the bending area BA (or a portion of the bending area BA) is located under the display panel 100. In an example in which the bending area BA is bent and located under the display panel 100, the plurality of driver ICs 200 and the circuit boards 300 may be located under the display panel 100.

The pad area PDA may be the lower edge area of the display panel 100. The display panel 10 may include, disposed in the pad area PDA, display pads PD connected to the circuit boards 300, and first and second driving pads connected to the driver ICs 200.

The display panel 10 may include, disposed in the pad area PDA, display pads DP connected to the circuit boards 300. The display pads DP may be disposed at one edge of the display panel 100. For example, the display pads DP may be disposed at the lower edge of the display panel 100.

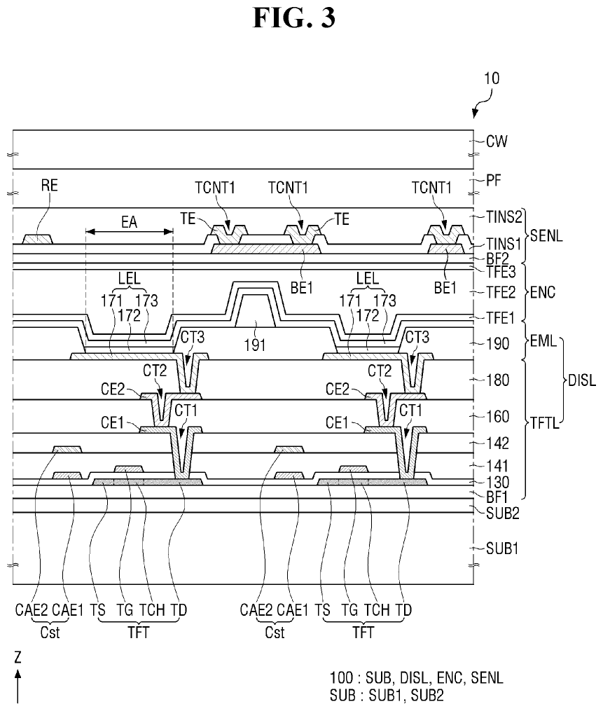

In the display device 10 according to one or more embodiments, the display panel 100 may include cutting areas CA. The cutting areas CA may be formed by partially removing a second substrate SUB2 (see FIG. 3) in the bending area BA, example aspects of which are later described herein. For example, aspects of the present disclosure include processes for forming or establishing the cutting areas CA by partially removing the second substrate SUB2 in the bending area BA. The term “cutting area CA” may also be referred to as a “cut area CA.”

The cutting areas CA may be located in the bending area BA. The cutting areas CA may be located on the both sides of the bending area BA in the extension direction of the bending area BA, e.g., in the first direction (x-axis direction). The cutting area CA may have a shape recessed toward the inside of the display panel 100 in the direction in which the bending area BA is extended. For example, as shown in FIG. 2, the cutting area CA on the left side of the bending area BA may be recessed in the first direction (x-axis direction), while the cutting area CA on the right side of the bending area BA may be recessed in a direction (negative x-axis direction) opposite to the first direction (x-axis direction).

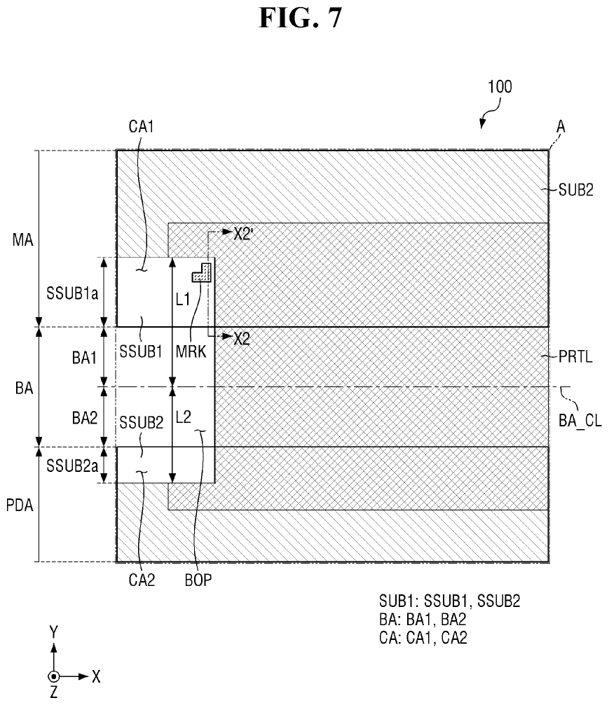

According to one or more embodiments of the present disclosure, the cutting areas CA of the display device 10 may support improved visibility of an alignment mark MRK (see FIG. 7). Accordingly, for example, the improved visibility may support improved alignment accuracy of the elements of the display device 10 when the display device 10 is bent. The cutting areas CA will be described in detail later with reference to the following figures, for example, at FIG. 7 and the like. References to instances of when the display device 10 is bent may refer to a bent state (or folded state) of the display device 10.

The driver integrated circuits (ICs) 200 may generate data voltages, supply voltages, scan timing signals, and other signals. The driver ICs 200 may output data voltages, supply voltages, scan timing signals, and other signals.

The driver ICs 200 may be disposed in the pad area PDA. The driver ICs 200 may be disposed between the display pads PD and the display area DA in the non-display area NDA. The driver ICs 200 may be attached to the non-display area NDA of the display panel 100 by a chip on glass (COG) technique. Alternatively or additionally, the driver ICs 200 may be attached to the circuit boards 300, respectively, by a chip on plastic (COP) technique.

The circuit boards 300 may be disposed on display pads DP disposed at one edge of the display panel 100. The circuit boards 300 may be attached to the display pads PD using a conductive adhesive member such as, for example, an anisotropic conductive film and an anisotropic conductive adhesive. Accordingly, for example, the circuit boards 300 may be electrically connected to signal lines of the display panel 100. The circuit boards 300 may be flexible printed circuit boards, flexible films such as, for example, chip on films.

FIG. 3 is a cross-sectional view showing an example of the display area of the display device 10 according to an embodiment of the present disclosure.

Referring to FIG. 3, the display device 10 may include a display panel 100, a polarizing film PF, and a cover window CW.

The display panel 100 may be an organic light-emitting display panel including light-emitting elements LEL each including an organic emissive layer 172. It should be understood, however, that embodiments supported by the present disclosure are not limited thereto. The display panel 110 may be a light-emitting display panel such as, for example, a quantum-dot light-emitting display panel including a quantum-dot emissive layer, an inorganic light-emitting display panel including an inorganic semiconductor, and a micro light-emitting display panel using micro or nano light-emitting diodes (micro LEDs or nano LEDs). In the descriptions herein, an organic light-emitting display panel is employed as an example of the display panel 100 for convenience of illustration.

The display panel 100 may include a substrate SUB, a display layer DISL, an encapsulation layer ENC, and a sensor electrode layer SENL.

The substrate SUB may include a first substrate SUB1 formed of a rigid material, and the substrate SUB may include a second substrate SUB2 formed of a polymer resin formed of a flexible material.

The first substrate SUB I may include a rigid material. For example, the substrate SUB may be formed of glass. The substrate SUB may be formed of ultra thin glass (UTG) having a thickness of approximately 500 μm or less. For example, aspects of the present disclosure include processes for forming the substrate SUB of glass (e.g., UTG, or the like).

The second substrate SUB2 may include a flexible material. The second substrate SUB2 may be formed of a polymer resin having a thickness smaller than the thickness of the first substrate SUB1. For example, the second substrate SUB2 may have a thickness of approximately 20 μm or less. The second substrate SUB2 may be formed of an organic material such as, for example, an acryl resin, an epoxy resin, a phenolic resin, a polyamide resin, and a polyimide resin. Since the second substrate SUB2 is formed of a polymer resin, the second substrate SUB2 may be referred to as a plastic substrate. In some embodiments, the second substrate SUB2 may have a multi-layer structure.

In some embodiments, the light transmittance of the first substrate SUB1 may be higher than the light transmittance of the second substrate SUB2. In some aspects, the refractive index of the first substrate SUB I may be lower than the refractive index of the second substrate SUB2.

The display layer DISL may include a thin-film transistor layer TFTL including a plurality of thin-film transistors and an emission material layer EML including a plurality of light-emitting elements.

The thin-film transistor layer TFTL may include a first buffer film BF1, a thin-film transistor TFT, a gate insulator 130, a first interlayer dielectric film 141, a capacitor Cst, a second interlayer dielectric film 142, a first data metal layer, a first organic film 160, a second data metal layer, and a second organic film 180.

The first buffer film BF1 may be disposed on the substrate SUB. The first buffer film BF1 may be formed of an inorganic material such as, for example, a silicon nitride layer, a silicon oxynitride layer, a silicon oxide layer, a titanium oxide layer, and an aluminum oxide layer. Alternatively, the first buffer film BF1 may be formed of multiple layers in which two or more of a silicon nitride layer, a silicon oxynitride layer, a silicon oxide layer, a titanium oxide layer, and an aluminum oxide layer are stacked.

An active layer may be disposed on the first buffer film BF1. A channel region TCH, a source region TS, and a drain region TD of the thin-film transistor TFT may each be formed of the active layer and may be disposed on the first buffer film BF1. The active layer may be formed of polycrystalline silicon, monocrystalline, low-temperature polycrystalline silicon, amorphous silicon, or an oxide semiconductor. In an example in which the active layer includes polycrystalline silicon or an oxide semiconductor material, the source region TS and the drain region TD in the active layer may be conductive regions doped with ions or impurities to have conductivity.

The gate insulator 130 may be disposed on the active layer of the thin-film transistor TFT. The gate insulator 130 may be formed of an inorganic layer, for example, a silicon nitride layer, a silicon oxynitride layer, a silicon oxide layer, a titanium oxide layer, or an aluminum oxide layer.

A first gate metal layer may be disposed on the gate insulator 130. A gate electrode TG of the thin-film transistor TFT, a first capacitor electrode CAE1 of a capacitor Cst, and scan lines may each be formed of the first gate metal layer and may be disposed on the gate insulator 130. The gate electrode G of the thin-film transistor TFT may overlap the channel region TCH in the third direction (z-axis direction). The first gate metal layer may be formed of a single layer or multiple layers of one or more of molybdenum (Mo), aluminum (Al), chromium (Cr), gold (Au), titanium (Ti), nickel (Ni), neodymium (Nd), copper (Cu), or an alloy thereof.

The first interlayer dielectric film 141 may be disposed on the first gate metal layer. The first interlayer dielectric film 141 may be formed of an inorganic layer, for example, a silicon nitride layer, a silicon oxynitride layer, a silicon oxide layer, a titanium oxide layer, or an aluminum oxide layer. The first interlayer dielectric film 141 may include a number of inorganic layers.

The second gate metal layer may be disposed on the first interlayer dielectric film 141. A second capacitor electrode CAE2 of the capacitor Cst may be formed of the second gate metal layer and be disposed on the first interlayer dielectric film 141. The second capacitor electrode CAE2 may overlap the first capacitor electrode CAE1 in the third direction (z-axis direction). Therefore, the capacitor Cst may be formed by the first capacitor electrode CAE1, the second capacitor electrode CAE2, and an inorganic insulating dielectric film disposed between the first capacitor electrode CAE1, the second capacitor electrode CAE2, in which the inorganic insulating dielectric film serves as a dielectric film. The second gate metal layer may be formed of a single layer or multiple layers of one or more of molybdenum (Mo), aluminum (Al), chromium (Cr), gold (Au), titanium (Ti), nickel (Ni), neodymium (Nd), copper (Cu), or an alloy thereof.

A second interlayer dielectric film 142 may be disposed on the second gate metal layer. The second interlayer dielectric film 142 may be formed of an inorganic layer, for example, a silicon nitride layer, a silicon oxynitride layer, a silicon oxide layer, a titanium oxide layer, or an aluminum oxide layer. The second interlayer dielectric film 142 may include a number of inorganic layers.

The first data metal layer may be disposed on the second interlayer dielectric film 142. First connection electrodes CE1 and data lines may be formed of the first data metal layer and be disposed on the second interlayer dielectric film 142. The first connection electrode CE1 may be connected to the drain region TD through a first contact hole CT1 penetrating the gate insulator 130, the first interlayer dielectric film 141, and the second interlayer dielectric film 142. The first data metal layer may be formed of a single layer or multiple layers of one or more of molybdenum (Mo), aluminum (Al), chromium (Cr), gold (Au), titanium (Ti), nickel (Ni), neodymium (Nd), copper (Cu), or an alloy thereof.

A first organic film 160 may be disposed over the first connection electrode CE1 for providing a flat surface over the thin-film transistors TFT having uneven heights. For example, the first organic film 160 may planarize the thin-film transistors TFT. The first organic film 160 may be formed as an organic layer such as, for example, an acryl resin, an epoxy resin, a phenolic resin, a polyamide resin and a polyimide resin.

A second data metal layer may be disposed on the first organic film 160. Second connection electrodes CE2 may be formed of the second data metal layer and be disposed on the first organic film 160. The second data metal layer may be connected to the first connection electrode CE1 through a second contact hole CT2 penetrating the first organic film 160. The second data metal layer may be formed of a single layer or multiple layers of one or more of molybdenum (Mo), aluminum (Al), chromium (Cr), gold (Au), titanium (Ti), nickel (Ni), neodymium (Nd), copper (Cu), or an alloy thereof.

The second organic film 180 may be disposed on the second connection electrode CE2. The second organic film 180 may be formed as an organic layer such as, for example, an acryl resin, an epoxy resin, a phenolic resin, a polyamide resin and a polyimide resin.

In some embodiments, the second data metal layer including the second connection electrodes CE2 and the second organic film 180 may be omitted.

The emission material layer EML is disposed on the thin-film transistor layer TFTL. The emission material layer EML may include light-emitting elements LEL and a pixel-defining film 190.

Each of the light-emitting elements LEL may include a pixel electrode 171, an emissive layer 172, and a common electrode 173. In each of the emission areas EA, the pixel electrode 171, the emissive layer 172 and the common electrode 173 are stacked on one another sequentially, such that holes from the pixel electrode 171 and electrons from the common electrode 173 are combined with each other in the emissive layer 172 to emit light. In such a case, for example, the pixel electrode 171 may be an anode electrode and the common electrode 173 may be a cathode electrode.

A pixel electrode layer may be formed on the second organic film 180. For example, the pixel electrode 171 may be formed of the pixel electrode layer and be formed on the second organic film 180. The pixel electrode 171 may be connected to the second connection electrode CE2 through a third contact hole CT3 penetrating the second organic film 180. The pixel electrode layer may be formed of a single layer or multiple layers of one or more of molybdenum (Mo), aluminum (Al), chromium (Cr), gold (Au), titanium (Ti), nickel (Ni), neodymium (Nd), copper (Cu), or an alloy thereof.

In the top-emission structure where light exits from the emissive layer 172 toward the common electrode 173, the pixel electrode 171 may be formed of a single layer of molybdenum (Mo), titanium (Ti), copper (Cu) or aluminum (Al), or the pixel electrode 171 may be formed of a stack structure of aluminum and titanium (Ti/Al/Ti), a stack structure of aluminum and ITO (ITO/Al/ITO), an APC alloy, or a stack structure of an APC alloy and ITO (ITO/APC/ITO) in order to increase the reflectivity. The APC alloy may be an alloy of silver (Ag), palladium (Pd) and copper (Cu).

The pixel-defining film 190 may define the emission areas EA of the pixels. In an example, the pixel-defining film 190 may be formed on the second organic film 180 such that the pixel-defining film 190 exposes a part of the pixel electrode 171. The pixel-defining film 190 may cover the edges of the pixel electrode 171. The pixel-defining film 190 may be disposed inside the third contact hole CT3. In other words, the third contact hole CT3 may be filled with the pixel-defining film 190. The pixel-defining film 190 may be formed of an organic layer such as, for example, an acryl resin, an epoxy resin, a phenolic resin, a polyamide resin, and a polyimide resin.

A spacer 191 may be disposed on the pixel-defining film 190. The spacer 191 may support a mask during a process of fabricating the emissive layer 172. The spacer 191 may be formed of an organic layer such as, for example, an acryl resin, an epoxy resin, a phenolic resin, a polyamide resin, and a polyimide resin.

The emissive layer 172 is formed on the pixel electrode 171. The emissive layer 172 may include an organic material to emit light of a certain color. For example, the emissive layer 172 may include a hole transporting layer, an organic material layer, and an electron transporting layer. The organic material layer may include a host and a dopant. The organic material layer may include a material that emits a predetermined light, and the organic material layer may be formed using a phosphor or a fluorescent material.

The common electrode 173 is formed on the emissive layer 172. The common electrode 173 may be formed such that common electrode 173 covers the emissive layer 172. The common electrode 173 may be a common layer formed across the emission areas EA. A capping layer may be formed on the common electrode 173.

In the top-emission structure, the common electrode 173 may be formed of a transparent conductive material (TCP) such as, for example, ITO and IZO that can transmit light, or a semi-transmissive conductive material such as, for example, magnesium (Mg), silver (Ag) and an alloy of magnesium (Mg) and silver (Ag). When the common electrode 173 is formed of a semi-transmissive metal material, the light extraction efficiency can be increased by using microcavities.

The encapsulation layer ENC may be disposed on the emission material layer EML. The encapsulation layer ENC may include one or more inorganic films TFE1 and TFE3 supportive of preventing the permeation of oxygen or moisture into the emission material layer EML. In some aspects, the encapsulation layer ENC may include at least one organic film in order to protect the emission material layer EML from particles such as, for example, dust. For example, the encapsulation layer ENC may include a first inorganic encapsulation film TFE1, an organic encapsulation film TFE2, and a second inorganic encapsulation film TFE3.

The first inorganic encapsulation film TFE1 may be disposed on the common electrode 173, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be formed of multiple layers including one or more inorganic layers of a silicon nitride layer, a silicon oxynitride layer, a silicon oxide layer, a titanium oxide layer, and an aluminum oxide layer alternately stacked on one another. The organic encapsulation film TFE2 may be an organic film such as, for example, an acryl resin, an epoxy resin, a phenolic resin, a polyamide resin, a polyimide resin, or the like.

The sensor electrode layer SENL may be disposed on the encapsulation layer ENC. The sensor electrode layer SENL may include a second buffer film BF2, a first bridge BE1, a first sensor insulating film TINS1, sensor electrodes TE and RE, and a second sensor insulating film TINS2.

A second buffer film BF2 may be disposed on the encapsulation layer ENC. The second buffer film BF2 may include at least one inorganic film. For example, the second buffer film BF2 may be formed of multiple layers in which one or more inorganic layers of a silicon nitride layer, a silicon oxynitride layer, a silicon oxide layer, a titanium oxide layer and an aluminum oxide layer are alternately stacked on one another. In some embodiments, the display device 10 may omit the second buffer film BF2.

First bridges BE1 may be disposed on the second buffer film BF2. The first bridges BE1 may be formed of a single layer of molybdenum (Mo), titanium (Ti), copper (Cu), or aluminum (Al), or may be formed of a stack structure of aluminum and titanium (Ti/Al/Ti), a stack structure of aluminum and ITO (ITO/Al/ITO), an APC alloy, or a stack structure of an APC alloy and ITO (ITO/APC/ITO).

A first sensor insulating film TINS1 may be disposed on the first bridges BE1. The first sensor insulating film TINS1 may be formed of an inorganic layer, for example, a silicon nitride layer, a silicon oxynitride layer, a silicon oxide layer, a titanium oxide layer, or an aluminum oxide layer.

The sensor electrodes (e.g., driving electrodes TE and sensing electrodes RE) may be disposed on the first sensor insulating film TINS1. In some aspects, dummy patterns may be disposed on the first sensor insulating film TNIS1. In some embodiments, the driving electrodes TE, the sensing electrodes RE, and the dummy patterns do not overlap the emission areas EA. The driving electrodes TE, the sensing electrodes RE and the dummy patterns may be formed of a single layer of molybdenum (Mo), titanium (Ti), copper (Cu), or aluminum (Al), or may be formed of a stack structure of aluminum and titanium (Ti/Al/Ti), a stack structure of aluminum and ITO (ITO/Al/ITO), an APC alloy, or a stack structure of an APC alloy and ITO (ITO/APC/ITO).

The second sensor insulating film TINS2 may be disposed on the driving electrodes TE, the sensing electrodes RE, and the dummy patterns. The second sensor insulating film TINS2 may include at least one of an inorganic film and an organic film. The inorganic film may be a silicon nitride layer, a silicon oxynitride layer, a silicon oxide layer, a titanium oxide layer, or an aluminum oxide layer. The organic film may include an acryl resin, an epoxy resin, a phenolic resin, a polyamide resin, or a polyimide resin.

The polarizing film PF may be disposed on the sensor electrode layer SENL. The polarizing film PF may be disposed on the display panel 100 in order to reduce reflection of external light. The polarizing film PF may include a first base member, a linear polarizer, a retardation film such as, for example, a N/4 (quarter-wave) plate, and a second base member. The first base member, the retardation film, the linear polarizer, and the second base member of the polarizing film PF may be sequentially stacked on the display panel 100.

The cover window CW may be disposed on the polarizing film PF. The cover window CW may be attached onto the polarizing film PF by a transparent adhesive member such as, for example, an optically clear adhesive (OCA) film.

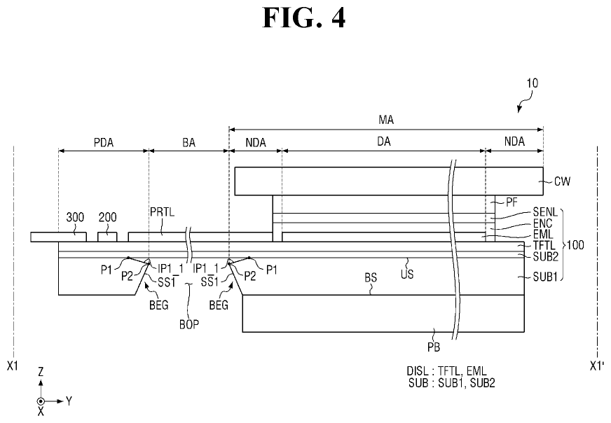

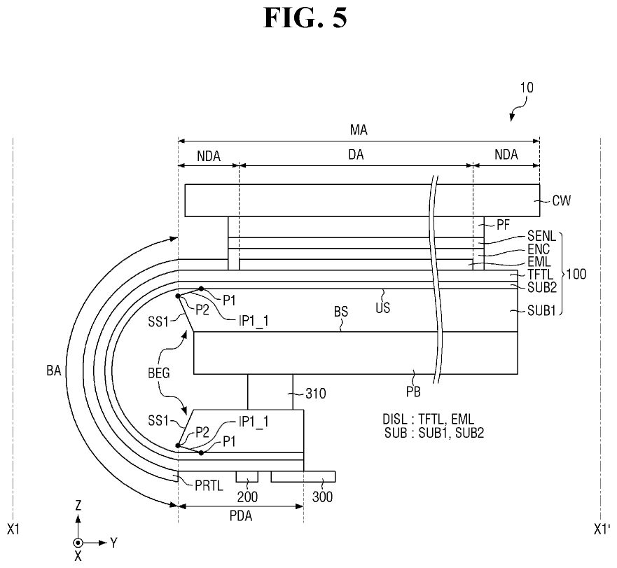

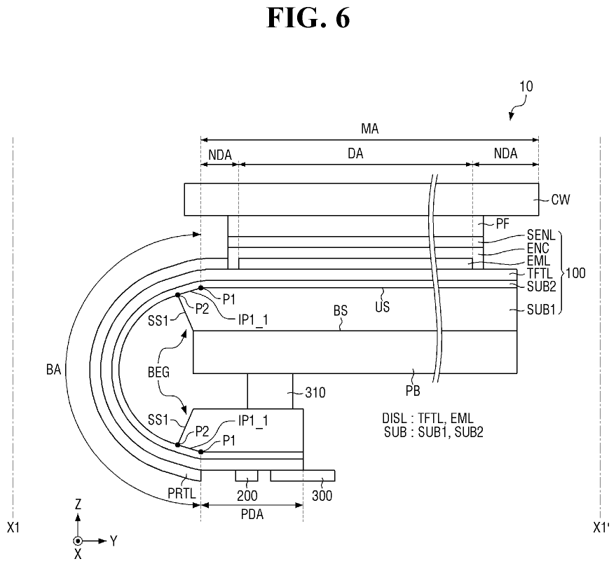

FIG. 4 is a cross-sectional view taken along line X1-X1′ of FIG. 1. FIG. 5 is a cross-sectional view showing an example of the display device 10 according to the embodiment of FIG. 4 when the display device 10 is bent. FIG. 6 is a cross-sectional view showing another example of the display device 10 according to the embodiment of FIG. 4 when the display device 10 is bent.

Referring to FIGS. 4 to 6, the display device 10 may further include a protective layer PRTL (also referred to herein as a protective film PRTL) and a panel bottom cover PB, in addition to the display panel 100, the polarizing film PF, the cover window CW, the driver IC 200, and the circuit board 300. The display panel 100 may include a substrate SUB, a display layer DISL, an encapsulation layer ENC, and a sensor electrode layer SENL.

Repeated descriptions of the display layer DISL, the encapsulation layer ENC, the sensor electrode layer SENL, the polarizing film PF, and the cover window CW previously provided herein will be omitted.

The substrate SUB may include a first substrate SUB1 formed of a rigid material, and a second substrate SUB2 formed of a polymer resin formed of a flexible material. In an example, the first substrate SUB1 may be disposed outside the bending area (e.g., the first substrate SUB1 is not be disposed in the bending area BA). For example, the first substrate SUB1 may include an opening BOP exposing the second substrate SUB2. Accordingly, for example, since the first substrate SUB1 formed of a rigid material is not disposed in the bending area BA, the bending area BA can be easily bent as shown in FIG. 5.

The protective layer PRTL may be disposed on the thin-film transistor layer TFTL in the bending area BA. The protective layer PRTL may be a layer for protecting the thin-film transistor layer TFTL exposed to the outside in the bending area BA. In some aspects, the protective layer PRTL can protect the thin-film transistor layer TFTL from tension or other external forces that may be applied to the thin-film transistor layer TFTL when the display device 10 is bent. The protective layer PRTL may be formed of an organic material such as, for example, an acryl resin, an epoxy resin, a phenolic resin, a polyamide resin, and a polyimide resin. In an example, the thickness of the protective layer PRTL may be, but is not limited to, approximately 60 μm or larger.

The panel bottom cover PB may be disposed on a second surface of the first substrate SUB1 of the display panel 100. The second surface of the first substrate SUB1 may be opposite to the first surface. For example, the panel bottom cover PB may be disposed on the lower surface BS of the first substrate SUB1. The panel bottom cover PB may be attached to the second surface of the first substrate SUB1 of the display panel 100 by an adhesive member. In an example, the adhesive member may be a pressure-sensitive adhesive (PSA), but is not limited thereto.

The panel bottom cover PB may include at least one of: a light-blocking member for absorbing light incident from outside the display device 10, a buffer member for absorbing external impacts, and a heat dissipating member for efficiently discharging heat from the display panel 100.

The bending area BA may be bent such that the driver IC 200 and the circuit board 300 are located under the display panel 100, as shown in FIG. 5. The circuit boards 300 may be attached to the lower surface of the panel bottom cover PB by an adhesive member 310. In an example, the adhesive member 310 may be a pressure-sensitive adhesive, but is not limited thereto.

According to some embodiments, the first substrate SUB1 may include an upper surface US, a lower surface BS, a first side surface SS1, and a first inclined surface IP1_1. The upper surface US of the first substrate SUB1 may be a side surface in the third direction (z-axis direction), and the lower surface BS may be opposite the side surface in the third direction (z-axis direction).

The first side surface SS1 may be positioned at an edge BEG of the bending area BA. The edge BEG of the bending area BA may refer to an edge formed by etching the first substrate SUB1 on the bending area BA.

The first side surface SS1 may be located between the upper surface US and the lower surface BS. The first side surface SS1 may be positioned at the edge BEG of the bending area BA. The first side surface SS1 may be an inclined surface. According to an embodiment of the present disclosure, the angle formed between the first side surface SS1 and the upper surface US may be an acute angle, and the angle formed between the first side surface SS1 and the lower surface BS may be an obtuse angle.

The inclined surface of the first side surface SS1 may be formed by attaching a protective film to the first substrate SUB1 and etching a portion of the first substrate SUB1 on the bending area BA (e.g., based on the protective film) during the process of fabricating the display device 10. For example, by attaching a protective film to the first substrate SUB1 except for a portion of the first substrate SUB1 in the bending area BA, the portions to which the protective film is not attached (e.g., the portion of the first substrate SUB1 located in the bending area BA) may be etched first prior to etching of the entirety of the first substrate SUB1. In an example, the portion of the first substrate SUB1 located in the bending area BA may be formed as inclined surfaces due to the isotropy of wet etching. After the portion of the first substrate SUB1 located in the bending area BA is etched to a predetermined thickness, the protective film may be removed and the entire first substrate SUB1 may be etched. In this manner, for example, the thickness of the first substrate SUB I can be reduced and the opening BOP exposing the second substrate SUB2 can be formed in the bending area BA.

The first inclined surface IP1_1 may be located between the upper surface US and the first side surface SS1. The first inclined surface IP1_1 may be an undercut formed between the first substrate SUB1 and the second substrate SUB2. When the first substrate SUB1 is etched during the process of fabricating the display device 10, the first inclined surface IP1_1 may be over etched as an etchant intrudes at the interface between the first substrate SUB1 and the second substrate SUB2.

According to an embodiment, the bending area BA may be located between two ends P2 of the edges BEG of the first substrate SUB1 in the bending area BA, as shown in FIG. 5. According to another embodiment, as shown in FIG. 6, due to the undercut formed between the first inclined surface IP1_1 and the upper surface US of the first substrate SUB1, the bending area BA may be located between two points P1 where the first inclined surface IP1_1 meets the upper surface US of the first substrate SUB1.

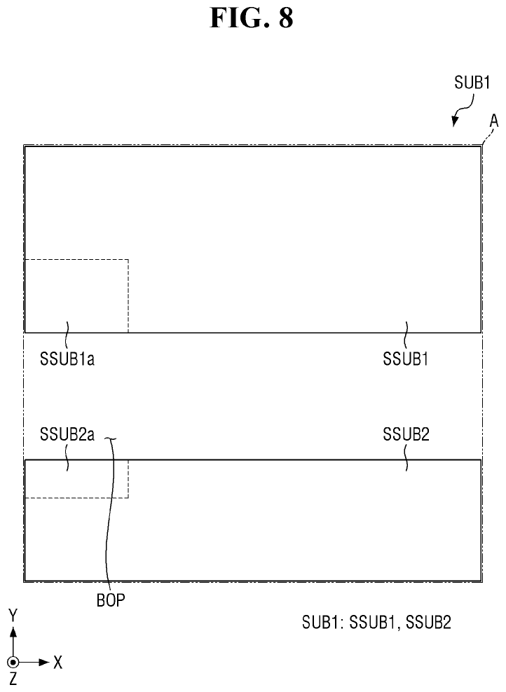

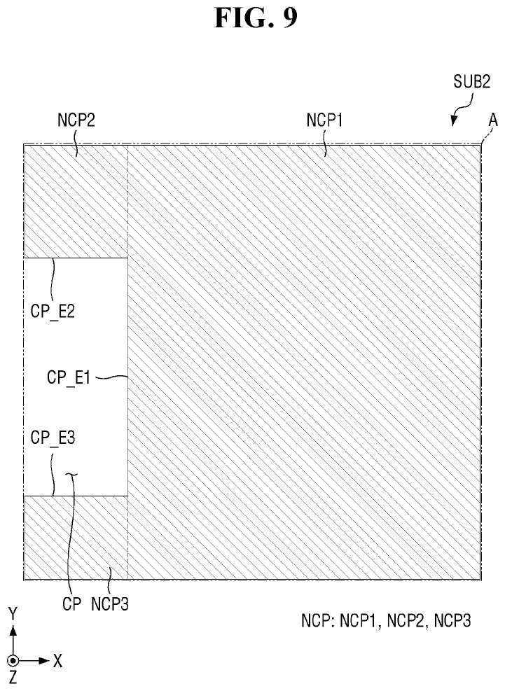

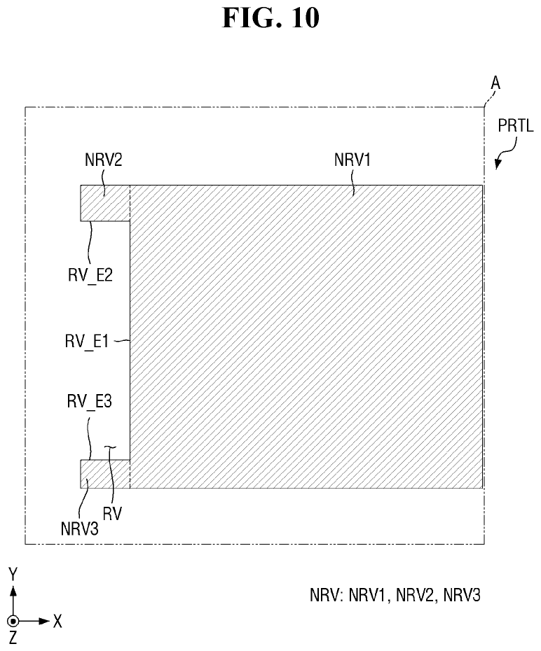

FIG. 7 is an enlarged view of area A of FIG. 2. FIG. 8 is a plan view showing a portion of a first substrate SUB1 according to an embodiment. FIG. 9 is a plan view showing a portion of a second substrate SUB2 according to an embodiment. FIG. 10 is a plan view showing a portion of a protective layer PRTL according to an embodiment of the present disclosure.

FIGS. 7 to 10 are views showing area A of FIG. 2, including the cutting areas CA. Since the cutting area CA on the left side is similar with the cutting area CA on the right side of the display device 10, the cutting area CA on the left side will be described as an example for convenience of illustration.

Referring to FIGS. 7 to 10, the display panel 100 may include a first substrate SUB1, a second substrate SUB2 disposed on the first substrate SUB1, and a protective layer PRTL disposed on the second substrate SUB2.

The first substrate SUB1 may include an opening BOP exposing the second substrate SUB2. For example, the first substrate SUB1 may include the opening BOP exposing the second substrate SUB2 in the bending area BA as shown in FIG. 8. The opening BOP of the first substrate SUB1 may be formed via an etching process. The opening BOP of the first substrate SUB1 may extend along the first direction (x-axis direction) in which the bending area BA extends. The length of the opening BOP of the first substrate SUB1 in the second direction (y-axis direction) may range from, but is not limited to, approximately 1,000 μm to 1,200 μm.

The first substrate SUB1 may include a first subsidiary substrate SSUB1 and a second subsidiary substrate SSUB2. In an example, the first subsidiary substrate SSUB1 is closer to the main area MA than to the pad area PDA with respect to the opening BOP, and the second subsidiary substrate SSUB2 is closer to the pad area PDA than to the main area MA with respect to the opening BOP.

The second substrate SUB2 may have a shape in which at least a portion of one or more ends of the second substrate SUB2 is recessed in the first direction (x-axis direction) or a direction opposite the first direction. For example, as shown in FIG. 9, the second substrate SUB2 may have a shape in which one end is recessed in the first direction (x-axis direction). In some embodiments, the second substrate SUB2 may have a shape in which at least a portion of one end of the second substrate SUB2 is recessed in the first direction (e.g., positive x-axis direction) and at least a portion of another end of the second substrate SUB2 is recessed in a direction (e.g., negative x-axis direction) opposite the first direction.

In some embodiments, the second substrate SUB2 may include cutting portions CP and non-cutting portions NCP. The term “cutting portion CP” may also be referred to as “cut portion CP.” The term “non-cutting portion NCP” may also be referred to as “non-cut portion NCP” or “uncut portion NCP.”

The cutting portions CP may be formed by removing parts of the second substrate SUB2. For example, aspects of the present disclosure include forming the cutting portions CP by removing one or more portions of the second substrate SUB2. The cutting portions CP may be located in the cutting areas CA, example aspects of which are later described herein. For example, the cutting portions CP may be located at both ends of the second substrate SUB2 in the first direction (x-axis direction), respectively. The cutting portions CP may extend across the main area MA, the bending area BA, and the pad area PDA.

The non-cutting portions NCP may include first to third non-cutting portions NCP1, NCP2 and NCP3. The first non-cutting portion NCP1 may be located on one side of the cutting portion CP in the first direction (x-axis direction). The second non-cutting portion NCP2 and the third non-cutting portion NCP3 may be located on a side of the first non-cutting portion NCP1 in the first direction (x-axis direction). In some aspects, the second non-cutting portion NCP2 and the third non-cutting portion NCP3 may respectively be located on two sides of the cutting portion CP in the second direction (y-axis direction). Although the non-cutting portions NCP have been described as the first to third non-cutting portions NCP1, NCP2 and NCP3 separately for convenience of illustration, the non-cutting portions NCP are not limited thereto. For example, the non-cutting portions NCP may be formed as an integral element that is not divided into subsidiary elements.

According to an embodiment, the cutting portion CP may have a square shape, as shown in FIG. 9. For example, a first edge CP_E1 between the cutting portion CP and the first non-cutting portion NCP1 may extend in the second direction (y-axis direction). A second edge CP_E2 between the cutting portion CP and the second non-cutting portion NCP2 may extend in the first direction (x-axis direction), and a third edge CP_E3 between the cutting portion CP and the third non-cutting portion NCP3 may extend in the first direction (x-axis direction). It should be understood, however, that embodiments supported by the present disclosure are not limited thereto. The shape of the cutting portion CP may be modified in a variety of ways in other embodiments. For example, the cutting portion CP may have a variety of shapes such as, for example, circular, oval, and polygonal shapes.

The protective layer PRTL may have a shape in which at least a portion of one or more ends of the protective layer PRTL is recessed in the first direction (x-axis direction). For example, as shown in FIG. 10, the protective layer PRTL may have a shape in which one end is recessed in the first direction (x-axis direction). In some embodiments, the protective layer PRTL may have a shape in which at least a portion of one end of the protective layer PRTL is recessed in the first direction (e.g., positive x-axis direction) and at least a portion of another end of the protective layer PRTL is recessed in a direction (e.g., negative x-axis direction) opposite the first direction.

In some embodiments, the protective layer PRTL may include one or more removed portions RV and one or more non-removed portions NRV.

The removed portions RV may be formed by partially removing the protective layer PRTL. The term “removed portion RV” may refer to an area or region absent the protective layer PRTL or from which a portion of the protective layer PRTL. References to a removed portion RV may refer to a single removed portion RV or multiple removed portions RV included in the removed portion RV. The removed portions RV may be located in the cutting areas CA, example aspects of which are later described herein. For example, the removed portions RV may be located at the both ends of the protective layer PRTL in the first direction (x-axis direction), respectively. The removed portions RV may extend across the main area MA, the bending area BA and the pad area PDA.

The non-removed portions NRV may include first to third non-removed portions NRV1, NRV2, and NRV3. The first non-removed portion NRV1 may be located on one side of the removed portion RV in the first direction (x-axis direction). The second non-removed portion NRV2 and the third non-removed portion NRV3 may be located at a side of the first non-removed portion NRV1 in the first direction (x-axis direction). The second non-removed portion NRV2 and the third non-removed portion NRV3 may be located at two sides of the removed portion RV in the second direction (y-axis direction), respectively. Although the non-removed portions NRV have been described as the first to third non-removed portions NRV1, NRV2 and NRV3 separately for convenience of illustration, the non-removed portions NRV are not limited thereto. The non-removed portions NRV may be formed as an integral element that is not divided into subsidiary elements.

According to an embodiment, the removed portion RV may have a square shape, as shown in FIG. 10. For example, a fourth edge RV_E1 between the removed portion RV and the first non-removed portion NRV1 may extend in the second direction (y-axis direction). A fifth edge RV_E2 between the removed portion RV and the second non-removed portion NRV2 may extend in the first direction (x-axis direction), and a sixth edge CP_E3 between the removed portion RV and the third non-removed portion NRV3 may extend in the first direction (x-axis direction). It should be understood, however, that embodiments supported by the present disclosure are not limited thereto. The shape of the removed portion CP may be modified in a variety of ways in other embodiments. For example, the removed portion RV may have a variety of shapes such as, for example, circular, oval, and polygonal shapes.

With reference to the example illustrated at FIG. 7, the display panel 100 may include a cutting area CA. The cutting area CA may extend in the second direction (y-axis direction) across the main area MA, the bending area BA, and the pad area PDA. The cutting area CA may be formed by removing parts of the second substrate SUB2. A part of the protective layer PRTL may be removed from the cutting area CA. The term “cutting area CA” may refer to areas or regions where portions of the second substrate and/or portions of the protective layer PRTL have been removed.

The bending area BA may include a first bending area BA1 closer to the main area MA, and a second bending area BA2 closer to the pad area PDA, with respect to a center line BA_CL of the bending area BA. In some embodiments, the length of the first bending area BA1 may be equal to the length of the second bending area BA2 in the second direction (y-axis direction).

The cutting area CA may include a first cutting area CA1 and a second cutting area CA2. The first cutting area CA1 may be closer to the main area MA than to the pad area PDA with respect to the center line BA_CL of the bending area BA, and the second cutting area CA2 may be closer to the pad area PDA than to the main area MA with respect to the center line BA_CL of the bending area BA. Expressed another way, the cutting area CA may be divided into the first cutting area CA1 and the second cutting area CA2 based on the center line BA_CL of the bending area BA. The first cutting area CA1 may be closer to the main area MA, and the second cutting area CA2 may be closer to the pad area PDA.

The first cutting area CA1 may overlap the first bending area BA1 and the first subsidiary substrate SSUB1. The second cutting area CA2 may overlap the second bending area BA2 and the second subsidiary substrate SSUB2.

The first subsidiary substrate SSUB1 may include a first non-overlapping portion SSUB1a. At the first non-overlapping portion SSUB1a, the first sub-substrate SSUB1 may not overlap the second substrate SUB2 or the protective layer PRTL. Alternatively, at the first non-overlapping portion SSUB1a, the first subsidiary substrate SSUB1 may overlap the cutting portion CP of the second substrate SUB2 and the removed portion RV of the protective layer PRTL. The first non-overlapping portion SSUB1a may be disposed in the first cutting area CA1.

The second subsidiary substrate SSUB2 may include a second non-overlapping portion SSUB2a. At the second non-overlapping portion SSUB2a, the second sub-substrate SSUB2 may be disposed such that the sub-substrate SSUB2 does not overlap the second substrate SUB2 or the protective layer PRTL. For example, at the second non-overlapping portion SSUB2a, the second subsidiary substrate SSUB2 may overlap the cutting portion CP of the second substrate SUB2 and the removed portion RV of the protective layer PRTL, such that second sub-substrate SSUB2 does not overlap non-removed portions of the second substrate SUB2 or the protective layer PRTL. The second non-overlapping portion SSUB2a may be disposed in the second cutting area CA2.

In the display device 10 according to the example embodiment described with reference to FIGS. 7 to 10, the protective layer PRTL includes the removed portion RV. That is, in the display device 10 according to this the example embodiment described with reference to FIGS. 7 to 10, a portion of the protective layer PRTL has been removed, and the absence of the protective layer PRTL as described may prevent cracks in the thin-film transistor layer TFTL (see FIG. 5) from forming when the display device 10 is bent. When the protective layer PRTL is applied on the second substrate SUB2, the thickness of the ends (e.g., the ends in the first direction (x-axis direction)) of the display device 10 may be smaller than the thickness of the center of the display device 10 due to surface tension and/or other factors (e.g., the removal of portions of the protective layer PRTL). If the display device 10 is bent and thinner portions (e.g., thinner end portions) of the protective layer PRTL have not been removed, cracks may occur in the thin-film transistor layer TFTL (see FIG. 5). Such cracks may propagate to the lines in the bending area BA or the pad area PDA, causing defects. By removing the thinner end portions of the protective layer PRTL in accordance with one or more embodiments of the present disclosure as described herein, the reliability of the display device 10 can be improved.

In some aspects, the display panel 100 may further include an alignment mark MRK. The alignment mark MRK may be disposed on the first non-overlapping portion SSUB1a of the first subsidiary substrate SSUB1. In an example, the alignment mark MRK may be disposed such that the alignment mark MRK does not overlap the second substrate SUB2 or the protective layer PRTL. Alternatively, the alignment mark MRK may overlap the cutting portion CP of the second substrate SUB2 and the removed portion RV of the protective layer PRTL, such that alignment mark MRK does not overlap the second substrate SUB2 or the protective layer PRTL. The alignment mark MRK may include, but is not limited to, a metallic material.

Although the alignment mark MRK is shown in an L-shape in the drawings, embodiments supported by the present disclosure are not limited thereto. For example, the shape of the alignment mark MRK may be modified in a variety of ways as long as the alignment mark MRK includes a side or line facing one or more borders of the cutting portion CP.

Although the drawings illustrate the alignment mark MRK as disposed on the first subsidiary substrate SSUB1, the alignment mark MRK is not limited thereto. In some alternative and/or additional embodiments, the alignment mark MRK may be disposed on the second subsidiary substrate SSUB2. In an embodiment, multiple alignment marks MRK may be respectively disposed on the first subsidiary substrate SSUB1 and on the second subsidiary substrate SSUB2

The alignment mark MRK may be used to check the alignment of the elements disposed in the main area MA and the elements disposed in the pad area PDA when the display device 10 is bent. According to one or more embodiments, the cutting areas CA of the display device 10 may support improved visibility of the alignment mark MRK, such that the alignment accuracy of the elements when the display device 10 is bent can be increased.

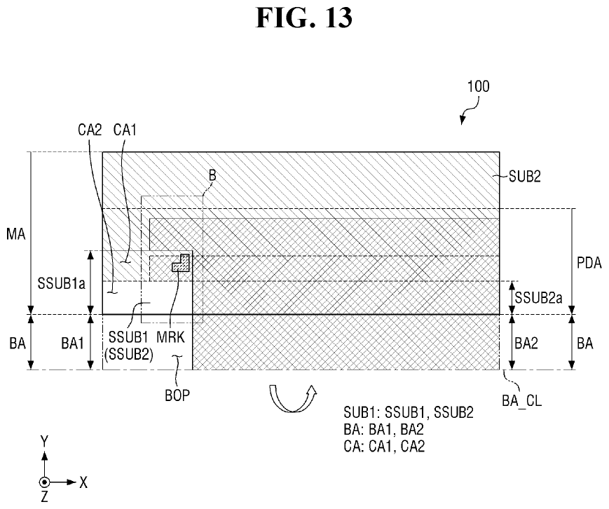

Specifically, the alignment mark MRK can be recognized using an optical device. As described herein, the light transmittance of the first substrate SUB1 may be higher than the light transmittance of the second substrate SUB2, and the refractive index of the first substrate SUB1 may be lower than the refractive index of the second substrate SUB2. Accordingly, for example, light emitted from the optical device may be less distorted when passing through the first substrate SUB1 compared to when passing through the second substrate SUB2. Accordingly, for example, the visibility of the alignment mark MRK can be improved by disposing or positioning the alignment mark MRK on the first non-overlapping portion SSUB1a of the first subsidiary substrate SSUB1. Example aspects of disposing or positioning the alignment mark MRK on the first non-overlapping portion SSUB1a will be described in detail later with reference to, for example, FIGS. 13 to 15.

In some embodiments, the length L1 of the first cutting area CA1 may be greater than the length L2 of the second cutting area CA2 in the second direction (y-axis direction). In the display device 10 according to one or more embodiments, as the length L1 of the first cutting area CA1 is greater than the length L2 of the second cutting area CA2, embodiments of the display device 10 support easily checking the alignment of the elements when the display device 10 is bent even though the alignment mark MRK is disposed only on the subsidiary substrate SSUB1. For example, when the display device 10 is bent, the elements can be aligned by comparing the position of the alignment mark MRK on the first subsidiary substrate SSUB1 with the position of the second substrate SUB2 disposed in the pad area PDA. Example aspects of aligning the elements by comparing the position of the alignment mark MRK with the position of the second substrate SUB2 will be described in detail later with reference to, for example, FIGS. 13 to 15.

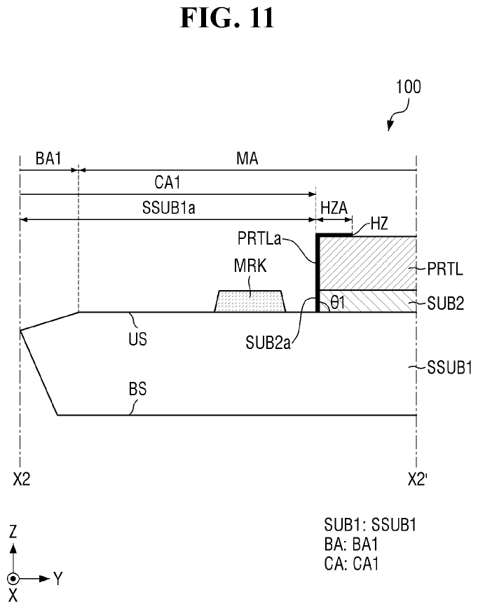

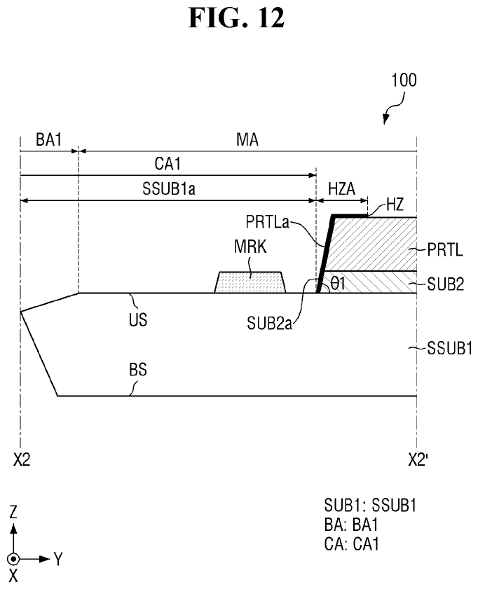

FIG. 11 is a cross-sectional view showing an example, taken along line X2-X2′ of FIG. 7. FIG. 12 is a cross-sectional view showing another example, taken along line X2-X2′ of FIG. 7.

Referring to FIGS. 11 and 12 in combination with FIGS. 7 to 10, the second substrate SUB2 and the protective layer PRTL may include a processing mark HZ at an end of the cutting area CA. For example, the second substrate SUB2 and the protective layer PRTL (or portions of the second substrate SUB2 and the protective layer PRTL) may be removed via a laser cutting process in the cutting area CA. Due to the energy of the laser, the physical properties of the second substrate SUB2 and the protective layer PRTL may change in the respective areas of the second substrate SUB2 and the protective layer PRTL adjacent to the cut portion. That is to say, the processing mark HZ of the second substrate SUB2 and the protective layer PRTL may be a heat affected zone HAZ affected by the energy of the laser. The length of the processing mark zone HZA, where the processing mark HZ is formed, may be approximately 10 μm to 100 μm in the second direction (y-axis direction).

Although in the example drawings, the processing mark HZ is formed on a side surface SUB2a of the second substrate SUB2, a side surface PRTLa of the protective layer PRTL, and an upper surface of the protective layer PRTL, embodiments supported by the present disclosure are not limited thereto. For example, the processing mark HZ may be alternatively and/or additionally formed at the interface between the second substrate SUB2 and the protective layer PRTL within the processing mark zone HZA, inside the second substrate SUB2 and/or the protective layer PRTL.

According to an embodiment, as shown in FIG. 11, the side surface SUB2a of the second substrate SUB2 and the side surface PRTLa of the protective layer PRTL may be vertical surfaces. For example, the angle θ1 formed by the side surface SUB2a of the second substrate SUB2 and the side surface PRTLa of the protective layer PRTL with the upper surface US of the first substrate SUB1 may be 90 degrees. According to another embodiment, as shown in FIG. 12, the side surface SUB2a of the second substrate SUB2 and the side surface PRTLa of the protective layer PRTL may be inclined surfaces. For example, the angle θ1 formed by the side surface SUB2a of the second substrate SUB2 and the side surface PRTLa of the protective layer PRTL with the upper surface US of the first substrate SUB1 may be equal to or greater than 45 degrees and less than 90 degrees. Depending on laser exit angle, the angle θ1 formed by the side surface SUB2a of the second substrate SUB2 and the side surface PRTLa of the protective layer PRTL with the upper surface US of the first substrate SUB1 may range between 45 degrees and 90 degrees.

In some embodiments, as shown in FIGS. 7, 9, and 10, the border of the cutting portion CP and the border of the removed portion RV may coincide with each other when viewed from the top (e.g., viewed according to a plan view). For example, the first to third edges CP_E1, CP_E2 and CP_E3 may coincide with the fourth to sixth edges RV_E1, RV_E2 and RV_E3. Expressed another way, respective coordinates of the first to third edges CP_E1, CP_E2 and CP_E3 according to the plan view may be the same as respective coordinates of the fourth to sixth edges RV_E1, RV_E2 and RV_E3. The terms “border” and “boundary” may be used interchangeably herein.

As used herein, the phrase that the border of the cutting portion CP and the border of the removed portion RV coincide with each other may mean that the side surface SUB2a of the second substrate SUB2 and the side surface PRTLa of the protective layer PRTL coincide with each other when the side surface SUB2a and the side surface PRTLa are vertical surfaces as shown in FIG. 11 and/or when the side surface SUB2a and the side surface PRTLa are inclined surfaces as shown in FIG. 12. Descriptions herein of elements that “coincide with each other” may mean that respective coordinates of the elements are the same.

For example, in some embodiments, the border of the cutting portion CP and the border of the removed portion RV may be described as coinciding with each other for cases in which the angle between the side surface SUB2a of the second substrate SUB2 and the upper surface US of the first substrate SUB1 is equal to the angle between the side surface PRTLa of the protective layer PRTL and the upper surface US of the first substrate SUB1, and the side surface SUB2a of the second substrate SUB2 is connected to the side surface PRTLa of the protective layer PRTL to form one surface.

In the display device 10 according to one or more embodiments, the second substrate SUB2 and the protective layer PRTL disposed in the cutting area CA may be simultaneously removed via a laser cutting process. Accordingly, process efficiency can be improved by performing a process of forming the removed portions RV by removing the non-uniform portions of the protective layer PRTL and simultaneously forming the cutting portions CP of the second substrate SUB2.

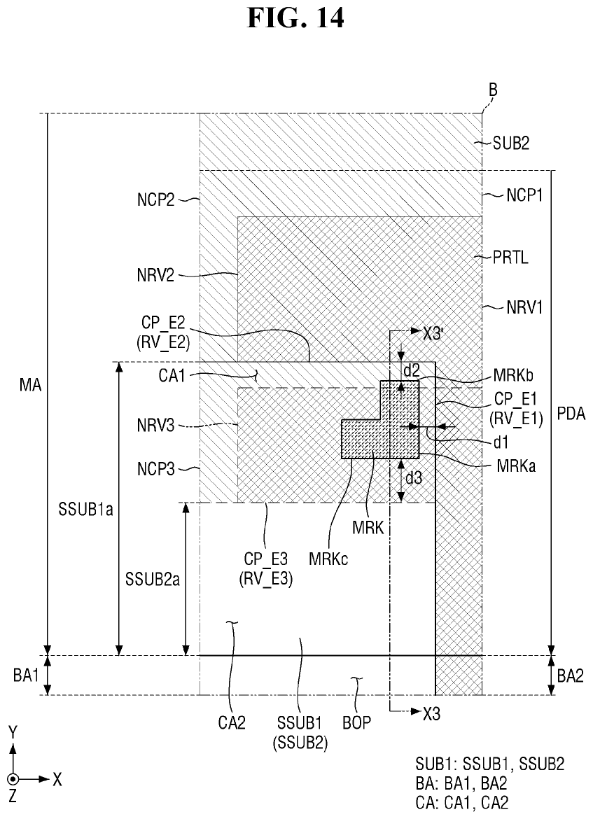

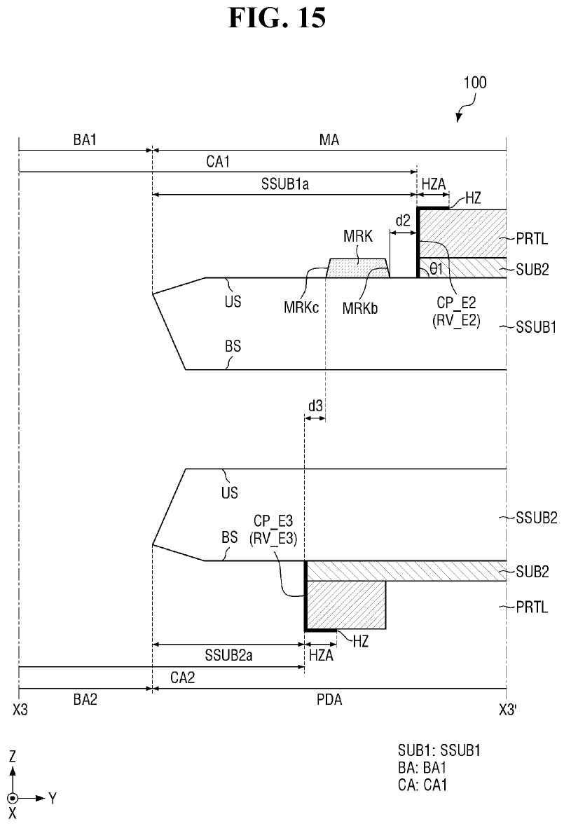

FIG. 13 is a plan view showing the display device 10 according to the embodiment of FIG. 7 when the display device 10 is bent. FIG. 14 is an enlarged view of area B of FIG. 13. FIG. 15 is a cross-sectional view, taken along line X3-X3′ in FIG. 14.

FIGS. 13 to 15 show the display device 10 when the display device 10 is bent. FIG. 13 shows that the second bending area BA2 and the pad area PDA are bent and are thus disposed under the first bending area BA1 and the main area MA with respect to the center line BA_CL of the bending area BA in FIG. 7. For example, FIG. 13 shows that the display panel 100 is bent at the center line BA_CL of the bending area BA in FIG. 7, such that the second bending area BA2 and the pad area PDA are disposed under the first bending area BA1 and the main area MA.

Referring to FIGS. 13 to 15 in conjunction with FIGS. 7 to 12, the display device 10 is bent such that the second bending area BA2 may overlap the first bending area BA1 and the pad area PDA may overlap the main area MA. The first non-overlapping portion SSUB1a of the first subsidiary substrate SSUB1 may overlap the second non-overlapping portion SSUB2a of the second subsidiary substrate SSUB2. The first cutting area CA1 may overlap the second cutting area CA2.

In some embodiments, an alignment mark MRK may overlap the first non-overlapping portion SSUB1a of the main area MA, and the alignment mark MRK may overlap the third non-cutting portion NCP3 and the third non-removed portion NRV3 of the pad area PDA.

A first end MRKa of the alignment mark MRK, which faces the first non-cutting portion NCP1, may be spaced apart from the first edge CP_E1 between the cutting portion CP and the first non-cutting portion NCP1 by a first distance d1. Alternatively, the first end MRKa may be disposed on the same line as the first edge CP_E1.

A second end MRKb of the alignment mark MRK, which faces the second non-cutting portion NCP2, may be spaced apart from the second edge CP_E2 between the cutting portion CP and the second non-cutting portion NCP2 by a second distance d2. Alternatively, the second end MRKb may be disposed on the same line as the second edge CP_E2.

A third end MRKc of the alignment mark MRK, which faces the third non-cutting portion NCP3, may be spaced apart from the third edge CP_E3 between the cutting portion CP and the third non-cutting portion NCP3 by a third distance d3. Alternatively, the third end MRKc may be disposed on the same line as the third edge CP_E3.

Accordingly, for example, the display device 10 according to the example embodiment supports checking whether elements of the display device 10 are correctly aligned when the display device 10 is bent, based on the distances d1, d2, and d3 between the alignment mark MRK and the border of the cutting portion CP of the second substrate SUB2 (i.e., the first to third edges CP_E1, CP_E2 and CP_E3).

Specifically, for example, if the length of the first cutting area CA1 and the length of the second cutting area CA2 are different from each other in the second direction (y-axis direction), the alignment mark MRK overlaps the first non-overlapping portion SSUB1a but not the second non-overlapping portion SSUB2a. The alignment mark MRK may overlap the third non-cutting portion NCP and the third non-removed portion NRV3.

In some aspects, since the transmittance of the first substrate SUB1 is higher than the transmittance of the second substrate SUB2, the first substrate SUB1 transmitting light may be relatively unrecognizable by an optical device, while the second substrate SUB2 transmitting less light may be relatively recognizable by the optical device. In some examples, since the transmittance of the first substrate SUB1 is higher than the transmittance of the second substrate SUB2, the alignment mark MRK may be more recognizable by the optical device when the alignment mark MRK is disposed on the first substrate SUB1 (having the higher transmittance) compared to when the alignment mark MRK is disposed on the second substrate SUB2.

In the display device 10 according to one or more embodiments, the visibility of the alignment mark MRK and the second substrate SUB2 disposed thereunder can be improved by overlapping the first non-overlapping portion SSUB1a with the alignment mark MRK. At the same time, embodiments of the present disclosure support utilizing the second substrate SUB2 as another alignment mark by overlapping the alignment mark MRK with the third non-cutting portion NCP of the second substrate SUB2. Accordingly, for example, even though the alignment mark MRK is disposed only on the first subsidiary substrate SSUB1, the alignment of the elements can be easily checked. The example aspects described herein can be equally applied to the relationship between the alignment mark MRK and the protective layer PRTL.

Hereinafter, a display device according to another embodiment of the present disclosure will be described. In the following description, the same or similar elements will be denoted by the same or similar reference numerals, and redundant descriptions will be omitted or briefly described.

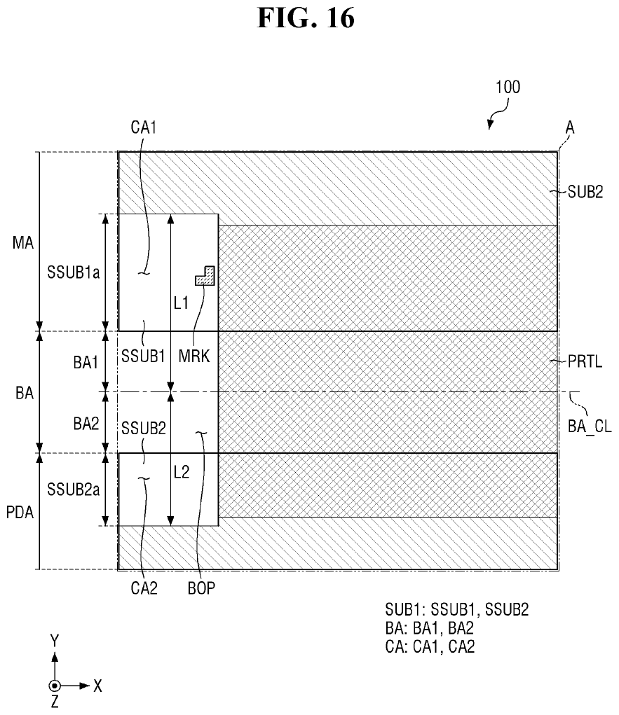

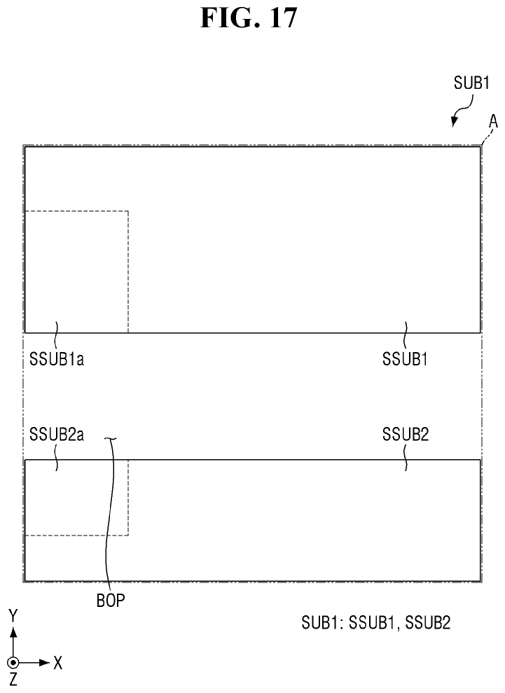

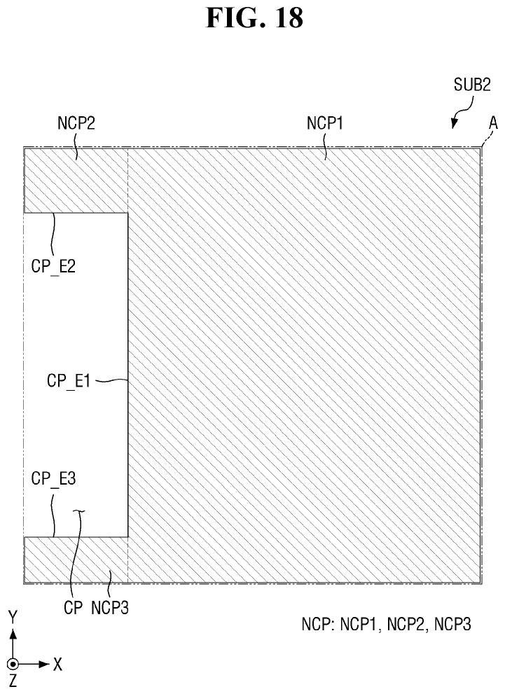

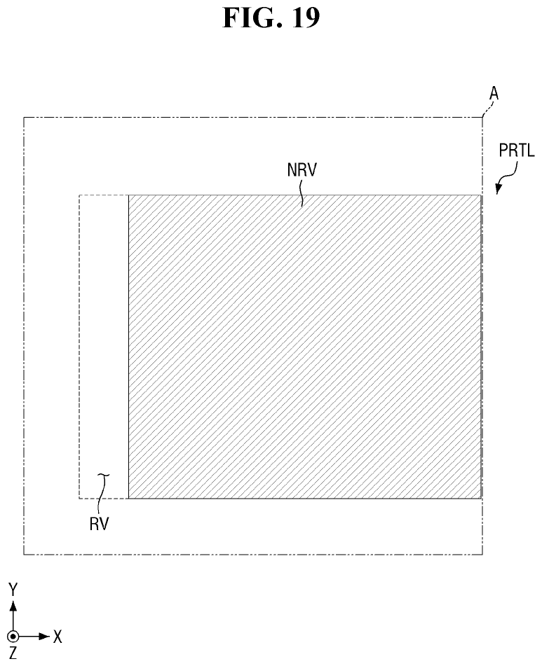

FIG. 16 is a plan view showing a portion of a display device according to another embodiment of the present disclosure. FIG. 17 is a plan view showing a portion of a first substrate SUB1 according to another embodiment. FIG. 18 is a plan view showing a portion of a second substrate SUB2 according to another embodiment. FIG. 19 is a plan view showing a portion of a protective layer PRTL according to another embodiment of the present disclosure.

The display device 10 according to the embodiment of FIGS. 16 to 19 includes aspects of the display device 10 according to the embodiment of FIG. 7 and the like described herein, and repeated descriptions of like elements are omitted for brevity. The display device 10 according to the embodiment of FIGS. 16 to 19 is different from the display device 10 according to the embodiment of FIG. 7 and the like in that the cutting areas CA respective to the embodiments are differently shaped.

More specifically, referring to FIG. 16, a protective layer PRTL may include a removed portion RV and a non-removed portion NRV. The removed portion RV may be located in the cutting area CA. The non-removed portion NRV may be located at one side of the removed portion RV. In an embodiment, the shape of the removed portion RV and the non-removed portion NRV may be a rectangle as shown in FIG. 19, but embodiments supported by the present disclosure are not limited thereto.

The length of the cutting area CA in the second direction (y-axis direction) in the display device 10 according to one or more embodiments may be greater than the length of the cutting area CA in the second direction DR2 (y-axis direction) in the display device 10 according to the embodiment described herein with reference to FIG. 7 and the like. For example, referring to FIG. 16 and FIG. 18, in the second direction (y-axis direction), the length of the cutting portions CP of the second substrate SUB2 may be greater than or equal to the length of the protective layer PRTL.

In the display device 10 according to one or more embodiments, the length of the cutting portion CP of the second substrate SUB2 in the second direction (y-axis direction) is greater than or equal to the length of the protective layer PRTL, the thinner portions (e.g., thinner end portions) of the protective layer PRTL in the first direction DR1 (x-axis direction) can be completely removed. Removing the thinner end portions of the protective layer PRTL in accordance with one or more embodiments of the present disclosure as described herein may prevent cracks in the thin-film transistor layer TFTL (see FIG. 5) and improve reliability of the display device 10.

Embodiments of the present disclosure support one or more processes (methods, flowcharts) for fabricating the display device 10 in accordance with the examples described herein. Descriptions that an element “may be disposed,” “may be formed,” and the like include processes (methods, flowcharts) for disposing or forming the element in accordance with example aspects described herein.

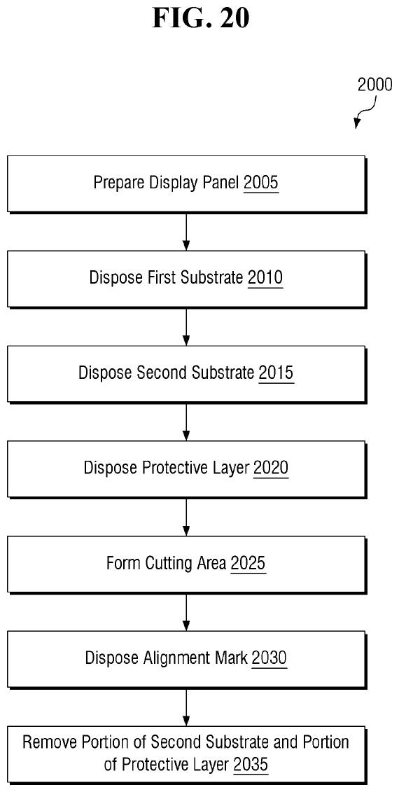

FIG. 20 illustrates an example flowchart of a method 2000 for fabricating a display device 10 in accordance with one or more embodiments of the present disclosure.

At 2005, the method 2000 includes preparing a display panel 100 including: a first area (e.g., display area DA) having a display area, a second area (e.g., non-display area NDA) spaced apart from the first area in a first direction, and a third area (e.g., bending area BA) located between the first area and the second area, wherein the third area is bendable.

In some aspects, at 2010, preparing the display panel 100 includes disposing a first substrate (e.g., first substrate SUB1) including a rigid material.

In some aspects, at 2015, preparing the display panel 100 includes disposing a second substrate (e.g., second substrate SUB2) on the first substrate, wherein the second substrate includes a flexible material.

In some aspects, at 2020, preparing the display panel 100 includes disposing a protective layer (e.g., protective layer PRTL) on the second substrate, wherein the protective layer overlaps the third area.

In some aspects, at 2025, preparing the display panel 100 includes forming, at the display panel, a cutting area (e.g., cutting area CA) that overlaps the third area, wherein the cutting area at least partially overlaps the first substrate. In some aspects, forming the cutting area includes removing one or more portions of the second substrate in the third area.

In some aspects, at 2030, preparing the display panel 100 includes disposing an alignment mark (e.g., alignment mark MRK) on the first substrate, at a location where the first substrate and the cutting area overlap each other.

In some aspects, 2035, preparing the display panel 100 includes removing a portion (e.g., cutting portion CP) of the second substrate and a portion (e.g., removed portion RV) of the protective layer from the cutting area.

In the descriptions of the flowcharts herein, the operations may be performed in a different order than the order shown, or the operations may be performed in different orders or at different times. Certain operations may also be left out of the flowcharts, one or more operations may be repeated, or other operations may be added to the flowcharts.

In concluding the detailed description, those skilled in the art will appreciate that many variations and modifications can be made to the example embodiments without substantially departing from the principles of the present disclosure. Therefore, the disclosed example embodiments of the invention are used in a generic and descriptive sense and not for purposes of limitation.

What is claimed is:

1. A display device comprising:
a display panel comprising: a first area having a display area, a second area spaced apart from the first area in a first direction, and a third area located between the first area and the second area and configured to bend,
wherein the display panel comprises:
a first substrate including a rigid material;
a second substrate disposed on the first substrate and including a flexible material;
a protective layer disposed on the second substrate and overlapping the third area; and
an alignment mark disposed on the first substrate,
wherein the display panel comprises a cutting area that overlaps the third area,
wherein a portion of the second substrate and a portion of the protective layer are removed from the cutting area,
wherein the first substrate at least partially overlaps the cutting area, and
wherein the alignment mark is disposed at a location where the first substrate and the cutting area overlap each other.

2. The display device of claim 1, wherein the cutting area is located at one or more ends of the third area in a second direction different from the first direction.

3. The display device of claim 1,
wherein the first substrate comprises:
an opening overlapping the third area;
a first subsidiary substrate disposed closer to the first area than to the second area with respect to the opening; and
a second subsidiary substrate disposed closer to the second area than to the first area with respect to the opening,
wherein the first subsidiary substrate comprises a first non-overlapping portion and the second subsidiary substrate comprises a second non-overlapping portion, and the first non-overlapping portion and the second non-overlapping portion are not overlapping the second substrate, and
wherein the alignment mark overlaps at least one of the first non-overlapping portion and the second non-overlapping portion.

4. The display device of claim 3, wherein the alignment mark, the first subsidiary substrate, the second subsidiary substrate, and the second substrate are arranged in an order of the alignment mark, the first subsidiary substrate, the second subsidiary substrate, and the second substrate along a thickness direction of the first substrate when the second substrate is bent at the third area.

5. The display device of claim 1, wherein the second substrate comprises a cutting portion located in the cutting area and a non-cutting portion located on one side of the cutting portion, and
wherein the alignment mark overlaps the cutting portion.

6. The display device of claim 5, wherein the non-cutting portion comprises:
a first non-cutting portion disposed on a first side of the cutting portion in a second direction different from the first direction;
a second non-cutting portion disposed on a second side of the cutting portion in the first direction; and
a third non-cutting portion disposed on a third side of the cutting portion in the first direction, wherein the third side is opposite the second side in the first direction.

7. The display device of claim 6, wherein the alignment mark overlaps the third non-cutting portion of the second substrate when the second substrate is bent at the third area.

8. The display device of claim 6, wherein the alignment mark comprises one or more sides facing a border of the cutting portion.

9. The display device of claim 5,
wherein the protective layer comprises a removed portion located in the cutting area and a non-removed portion located at one or more sides of the removed portion, and
wherein the alignment mark overlaps the removed portion.

10. The display device of claim 9, wherein the removed portion overlaps the cutting portion.

11. The display device of claim 9, wherein the non-removed portion comprises:
a first non-removed portion disposed on a first side of the removed portion in a second direction different from the first direction,
a second non-removed portion disposed on a second side of the removed portion in the first direction, and
a third non-removed portion disposed on a third side of the removed portion in the first direction, wherein the third side is opposite the second side in the first direction.

12. The display device of claim 9, wherein a boundary between the cutting portion and the non-cutting portion corresponds to a boundary between the removed portion and the non-removed portion in a thickness direction of the first substrate.

13. The display device of claim 12, wherein an angle formed between a side surface of the second substrate and a surface of the first substrate ranges from 45 degrees to 90 degrees at the boundary between the cutting portion and the non-cutting portion.

14. The display device of claim 12, further comprising a processing mark disposed at the boundary between the cutting portion and the non-cutting portion,
wherein a length of the processing mark in the first direction ranges from 10 μm to 100 μm.

15. The display device of claim 1,
wherein the cutting area comprises:
a first cutting area located closer to the first area than to the second area with respect to a center line of the third area, and
a second cutting area located closer to the second area than to the first area with respect to the center line of the third area, and
wherein a length of the first cutting area in the first direction is greater than a length of the second cutting area.

16. The display device of claim 1, wherein a transmittance of the first substrate is higher than a transmittance of the second substrate.

17. The display device of claim 1, wherein the first substrate further comprises:
a first surface on which the second substrate is disposed;
a second surface opposite to the first surface;
a first side surface disposed adjacent to the third area and located between the first surface and the second surface; and
a first inclined surface disposed between the first surface and the first side surface.

18. The display device of claim 1, wherein a length of the cutting area in the first direction is greater than or equal to a length of the protective layer in the first direction.

19. The display device of claim 18,
wherein the second substrate comprises a cutting portion located in the cutting area,
wherein the protective layer comprises a removed portion located in the cutting area,
wherein the cutting portion and the removed portion overlap each other, and
wherein the length of the cutting portion in the first direction is greater than or equal to a length of the removed portion in the first direction.

20. A method for fabricating a display device, the method comprising:
preparing a display panel comprising:
a first area having a display area;
a second area spaced apart from the first area in a first direction; and
a third area located between the first area and the second area, wherein the third area is bendable;
wherein preparing the display panel comprises:
disposing a first substrate including a rigid material;
disposing a second substrate on the first substrate, wherein the second substrate includes a flexible material;
disposing a protective layer on the second substrate, wherein the protective layer overlaps the third area;
forming, at the display panel, a cutting area that overlaps the third area, wherein the cutting area at least partially overlaps the first substrate, wherein forming the cutting area comprises removing one or more portions of the second substrate in the third area;
disposing an alignment mark on the first substrate, at a location where the first substrate and the cutting area overlap each other; and
removing a portion of the second substrate and a portion of the protective layer from the cutting area.
